(19) United States
(12) Patent Application Publication
(10) Pub. No.: US 2019/0085450 A1
(43) Pub. Date: Mar. 21, 2019

(54) SEMICONDUCTOR MANUFACTURING APPARATUS

(71) Applicant: Toshiba Memory Corporation, Minato-ku (JP)

(72) Inventors: Masakatsu Takeuchi, Obu (JP); Makoto Usuki, Kuwana (JP)

(73) Assignee: Toshiba Memory Corporation, Minato-ku (JP)

(21) Appl. No.: 15/914,373

(22) Filed: Mar. 7, 2018

(30) Foreign Application Priority Data
Sep. 15, 2017 (JP) 2017-178093

(51) Int. Cl. C23C 16/455

(52) U.S. Cl. CPC C23C 16/45548; H01L 21/0228

(57) ABSTRACT

According to one embodiment, in a semiconductor manufacturing apparatus, a first gas supply pipe is disposed between a gas supply source and a processing chamber. A first valve is disposed in the first gas supply pipe. The first valve includes a first valve seat forming a first opening, a first diaphragm, and a first pressing member capable of pressing the first diaphragm against the first valve seat. A second gas supply pipe is disposed between the gas supply source and the processing chamber. The second gas supply pipe is connected to the first gas supply pipe in parallel. A second valve is disposed in the second gas supply pipe. The second valve includes a second valve seat forming a second opening, a second diaphragm, and a second pressing member capable of pressing the second diaphragm against the second valve seat.

### CROSS-REFERENCE TO RELATED APPLICATIONS

This application is based upon and claims the benefit of priority from Japanese Patent Application No. 2017-178093, filed on Sep. 15, 2017; the entire contents of which are incorporated herein by reference.

### FIELD

Embodiments described herein relate generally to a semiconductor manufacturing apparatus.

### BACKGROUND

In semiconductor manufacturing apparatuses such as an atomic layer deposition (ALD) apparatus, a processing gas is supplied to a substrate in a processing chamber so that the substrate is processed. In this case, in order to improve substrate processing efficiency, it is desirable to improve supply efficiency of the processing gas to the processing chamber.

### BRIEF DESCRIPTION OF THE DRAWINGS

FIG. 1 is a view illustrating a configuration of a semiconductor manufacturing apparatus according to a first embodiment;

FIG. 2 is a cross-sectional view illustrating a configuration of a valve in the first embodiment;

FIGS. 3A and 3B are cross-sectional views illustrating an operation of the valve in the first embodiment;

FIG. 4 is a plan view illustrating an implementation configuration of a plurality of valves in the first embodiment;

FIG. 5 is a cross-sectional view illustrating an implementation configuration of a plurality of valves in the first embodiment;

FIG. 6 is a timing chart illustrating operations of a plurality of valves in the first embodiment;

FIG. 7 is a timing chart illustrating operations of a plurality of valves in a modified example of the first embodiment;

FIG. 8 is a view illustrating a configuration of a semiconductor manufacturing apparatus according to a second embodiment;

FIG. 9 is a flowchart illustrating an operation of the semiconductor manufacturing apparatus according to the second embodiment;

FIG. 10 is a view illustrating an operation of the semiconductor manufacturing apparatus according to the second embodiment;

FIG. 11 is a view illustrating an operation of the semiconductor manufacturing apparatus according to the second embodiment;

FIG. 12 is a view illustrating an operation of the semiconductor manufacturing apparatus according to the second embodiment; and

FIG. 13 is a view illustrating a configuration of a semiconductor manufacturing apparatus according to a third embodiment.

### DETAILED DESCRIPTION

In general, according to one embodiment, there is provided a semiconductor manufacturing apparatus including a processing chamber, a first gas supply pipe, a first valve, a second gas supply pipe, and a second valve. In the processing chamber, a substrate is processed. The first gas supply pipe is disposed between a gas supply source and the processing chamber. The first valve is disposed in the first gas supply pipe. The first valve includes a first valve seat forming a first opening, a first diaphragm, and a first pressing member capable of pressing the first diaphragm against the first valve seat. The second gas supply pipe is disposed between the gas supply source and the processing chamber. The second gas supply pipe is connected to the first gas supply pipe in parallel. The second valve is disposed in the second gas supply pipe. The second valve includes a second valve seat forming a second opening, a second diaphragm, and a second pressing member capable of pressing the second diaphragm against the second valve seat.

Exemplary embodiments of a semiconductor manufacturing apparatus will be explained below in detail with reference to the accompanying drawings. The present invention is not limited to the following embodiments.

### First Embodiment

In order to manufacture a semiconductor device, a semiconductor manufacturing apparatus according to a first embodiment supplies a processing gas to a substrate in a processing chamber and processes the substrate. The semiconductor manufacturing apparatus is, for example, an ALD apparatus which processes the substrate by using an atomic layer deposition (ALD) technique.

The ALD technique is known as a technique capable of uniformly depositing a thin film on a substrate. In the ALD technique, two or more types of processing gases (for example, a material gas and/or a reaction gas mainly composed of an element constituting a thin film to be formed) are alternately supplied onto the substrate, and a thin film can be formed on the substrate in units of atomic layers. At this time, flow rates of two or more types of processing gases are controlled in a pulse form, but a pulse waveform of a flow rate of each processing gas tends to have a rising period time and an attenuation period of time without becoming a delta function. If pulse timings of the respective processing gases in the processing chamber overlap, a non-ALD growth in which a substantially unintended amount of processing gas is supplied onto the substrate, and a non-uniform thin film is grown is likely to occur. To prevent the non-ALD growth, the pulse waveforms of the flow rates of the respective processing gases are separated by a purge interval period in which the processing gas is purged with purge gas (inert gas) in the processing chamber, and supply of other processing gas is prepared.

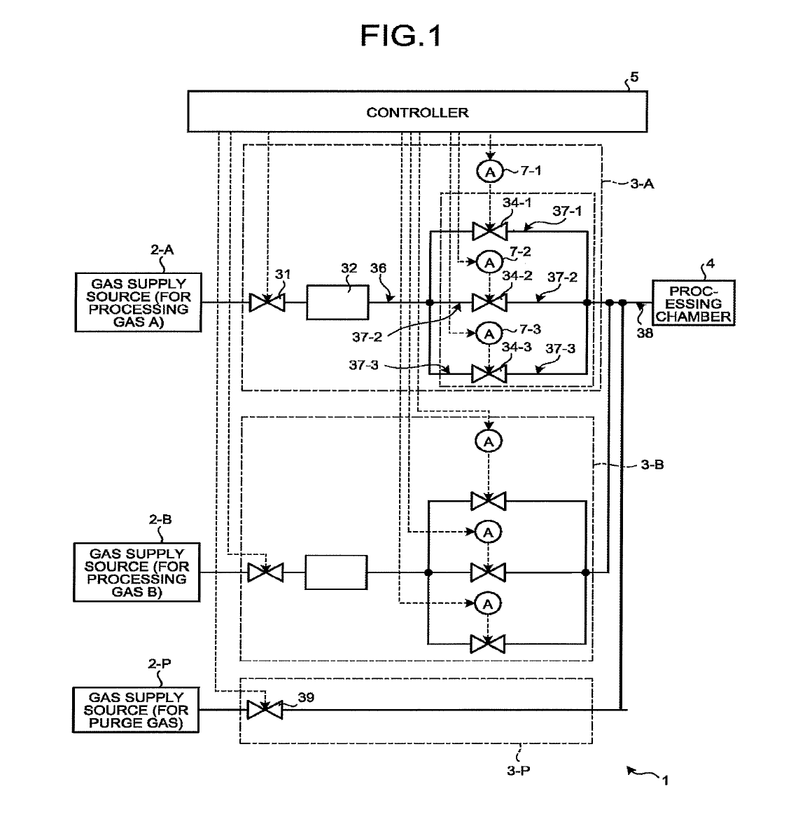

For example, a semiconductor manufacturing apparatus 1 is configured as illustrated in FIG. 1. FIG. 1 is a view illustrating a configuration of the semiconductor manufacturing apparatus 1. The semiconductor manufacturing apparatus 1 is configured to be able to supply a processing gas A, a processing gas B, and a purge gas to a processing chamber 4. The processing gas A and the processing gas B are gases of different compositions. Each of the processing gas A and the processing gas B can be arbitrarily selected according to a type of film to he deposited on the substrate. The processing gas A and the processing gas B used when nucleation for ALD growth is performed on the substrate may be identical to or different from those when ALD growth after nucleation is performed on the substrate. Further, an arbitrary inert gas can be applied as the purge gas. The purge gas may be, for example, Ar gas, N₂ gas, O₂ gas, N₂O gas, He gas, other inert gas, or a mixed gas thereof.

It should be noted that the semiconductor manufacturing apparatus 1 may be configured to supply one or more types of processing gas to the processing chamber 4 in addition to the processing gas ‘A’ and the processing gas ‘B’.

The semiconductor manufacturing apparatus includes a gas supply source 2-A, a gas supply system 3-A, a gas supply source 2-B, a gas supply system 3-B, a gas supply source 2-P, a gas supply system 3-P, the processing chamber 4, and a control 5.

The gas supply source 2-A, the gas supply source 2-B, and the gas supply source 2-P are gas supply sources (for example, gas cylinders) for the processing gas ‘A’, the processing gas ‘B’, and the purge gas, respectively. The gas supply system 3-A is arranged between the gas supply source 2-A and the processing chamber 4 and supplies the processing gas ‘A’ to the processing chamber 4 under the control of the controller 5. The gas supply system 3-B is arranged between the gas supply source 2-B and the processing chamber 4 and supplies the processing gas ‘B’ to the processing chamber 4 under the control of the controller 5. The gas supply system 3-P is arranged between gas supply source 2-P and the processing chamber 4 and supplies the purge gas to the processing chamber 4 under the control of the controller 5.

In a case in which the semiconductor manufacturing apparatus 1 is the ALD apparatus, in the gas supply systems 3-A and 3-B, the pressure of the processing gas to be supplied to the processing chamber 4 is controlled in a pulse form by the controller 5 using a valve 34, and thus a valve capable of performing an opening closing operation at a high speed (for example, in a microsecond order) is suitable as the valve 34, and a diaphragm valve can be used. At this time, the gas supply system 3-P includes a valve 39 (for example, an on-off valve), the controller 5 can cause the valve 39 to enter an open state during a purge interval period so that the purging operation can be performed in the processing chamber 4.

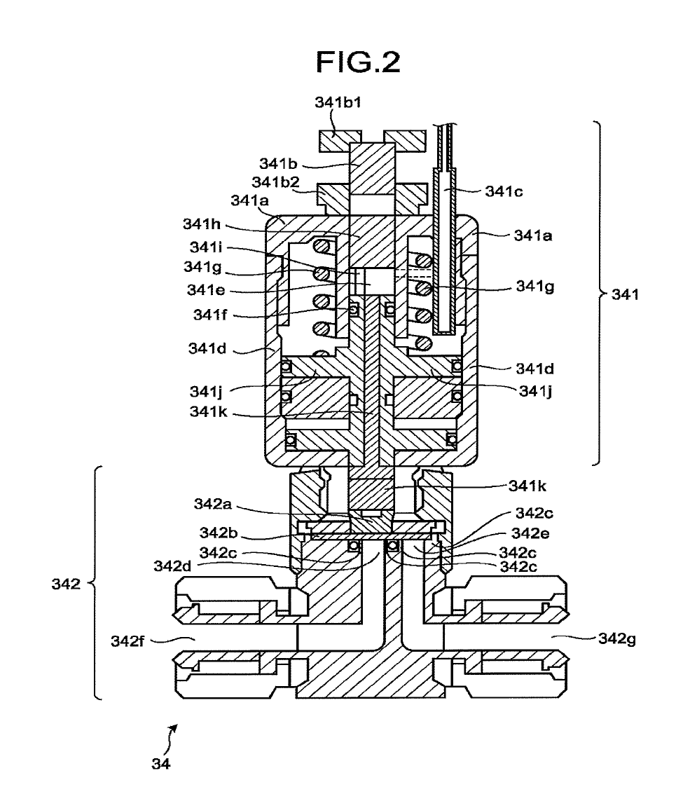

The valve 34 is configured, for example, as illustrated in FIG. 2. FIG. 2 is a cross-sectional view illustrating a configuration of the valve 34. The valve 34 is, for example, a diaphragm valve using a pneumatic actuator and includes an actuator assembly 341 and a valve assembly 342.

The actuator assembly 341 includes a bonnet 341a, an adjusting screw 341b, an auxiliary control port 341c, a wall portion 341d, an air chamber 341e, an O ring 341f, a spring 341g, pistons 341h and 341j, and piston rods 341i and 341k. The valve assembly 342 includes a valve stem 342a, a diaphragm 342b, a valve seat 342c, an inlet opening 342d, an outlet opening 342e, an inlet port 342f, and an outlet port 342g.

The adjusting screw 341b includes a nut 341b1 and a lock nut 341b2. The adjusting screw 341b is supported on the bonnet 341a and screwed to the bonnet 341a via the nut 341b1 and the lock nut 341b2. The auxiliary control port 341c communicates with the air chamber 341e formed to be surrounded by the bonnet 341a, the wall portion 341d, and the piston 341h. The auxiliary control port 341c is configured to be able to be supplied with, for example, an operation gas (air) adjusted to a high pressure from an air regulator 7 (see FIG. 1) by the controller 5. The air regulator 7 includes a motor, a compressor, an on-off valve, and the like. The controller 5 can control an air compression operation by the compressor by controlling a rotation operation of the motor and can control whether or not the high pressure air is supplied to the auxiliary control port 341c by performing control such that the on-off valve is opened or closed.

The O ring 341f seals the air chamber 341e. The spring 341g urges the piston 341j toward the valve assembly 342 side. The piston rod 341i couples the piston 341h with the piston 341j and transmits movement of the piston 341h to the piston 341j. The piston rod 341k is fixed to the inside of the piston 341j, and transmits the movement of the piston 341j to a valve stem 342a in the valve assembly 342.

The valve stem 342a is disposed on an opposite side to the inlet opening 342d and the outlet opening 342e with respect to the diaphragm 342b and configured to be able to press the diaphragm 342b against the valve seat 342c. The diaphragm 342b has flexibility and can be formed of a material mainly composed of, for example, a flexible plastic or an elastic material (such as rubber). The valve seat 342c faces the diaphragm 342b and forms the inlet opening 342d and the outlet opening 342e. The inlet opening 342d communicates with the inlet port 342f, and the processing gas can be supplied to the inlet opening 342d via the inlet port 342f. The outlet opening 342e communicates with the outlet port 342g, and the processing gas can be discharged via the outlet port 342g.

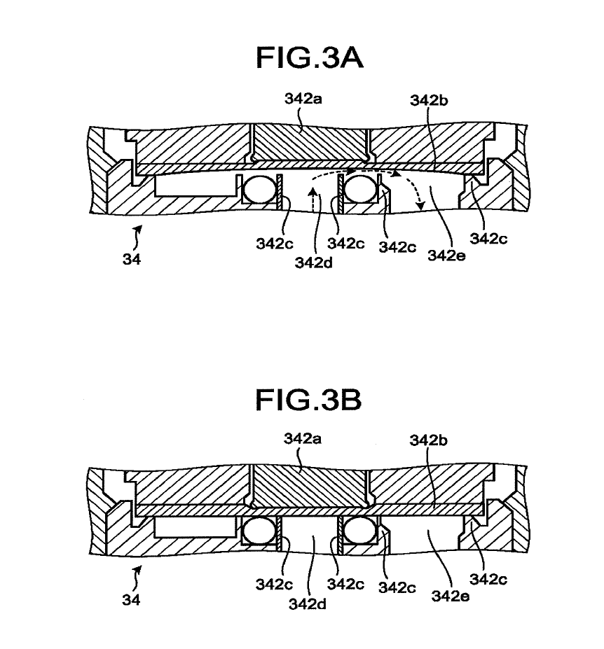

The valve 34 performs an opening/closing operation, for example, as illustrated in FIGS. 3A and 3B. FIGS. 3A and 3B are views illustrating an operation of the valve 34, FIG. 3A illustrates an open state of the valve 34, and FIG. 3B illustrates a closed state of the valve 34.

For example, the valve 34 is a normally closed type, and is configured to be automatically closed when supply of an operation gas (air) stops when an abnormality such as power failure occurs.

The air adjusted to the high pressure under the control of the controller 5 is supplied from the air regulator 7 (see FIG. 1) to the air chamber 341e via the auxiliary control port 341c (see FIG. 2). The high pressure air in the air chamber 341e pushes the piston 341h to the side opposite to the valve assembly 342, and causes an upward movement of the piston 341h to be transmitted to the valve stem 342a via the piston rod 341i, the piston 341j, and the piston rod 341k. Accordingly, the state in which the valve stem 342a pushes the diaphragm 342b against the valve seat 342c is released, and thus the valve (diaphragm valve) 34 enters the open state, and the processing gas can flow from the inlet opening 342d to the outlet opening 342e as indicated by a dashed arrow.

If the supply of the high pressure air to the air chamber 341e is stopped under the control of the controller 5, the piston 341j is urged by the spring 341g and pushed down toward the valve assembly 342, and a downward movement of the piston 341j is transmitted to the valve stem 342a via the piston rod 341k. Accordingly, the valve stem 342a returns to the state of pressing the diaphragm 342b against the valve seat 342c, and thus the valve (diaphragm valve) 34 is closed, and the flow of the processing gas from the inlet opening 342d to the outlet opening 342e is blocked.

In order to improve the efficiency of substrate processing by the semiconductor manufacturing apparatus 1 illustrated in FIG. 1, it is desirable to improve the supply efficiency of the respective processing gases (the processing gas ‘A’ and the processing gas ‘B’) to the processing chamber 4. However, as illustrated in FIGS. 2, 3A, and 3B, due to the configuration of the valve 34 that performs the opening/closing operation by pressing/releasing the diaphragm 342b toward/from the valve seat 342c by the valve stem 342a (or the operation of performing the opening/closing operation at a high speed), it is difficult to increase the gas supply amount to the processing chamber 4 with the single valve 34 even if, for example, a slight configuration change of increasing opening widths of the inlet opening 342d and the outlet opening 342e is made.

In this regard, the present embodiment parallelizing the connection of the valve 34 between a gas supply source 2 and the processing chamber 4 in the semiconductor manufacturing apparatus 1 so as to improve the supply efficiency of each processing gas to the processing chamber 4.

Specifically, each gas supply system 3 is configured as illustrated in FIG. 1. The following description will mainly proceed with the configuration for the processing gas ‘A’, but configurations of other processing gas (the processing gas B and the like) are similar to that of the processing gas ‘A’. For the sake of simplification of description, the processing gas ‘A’ is referred to simply as a processing gas, the gas supply source 2-A is referred to simply as a gas supply source 2, and a gas supply system 3-A is referred to simply as a gas supply system 3.

The gas supply system 3 includes a valve 31, a filling tank 32, a plurality of valves 34-1 to 34-3, and gas supply pipes 36, 37-1 to 37-3, and 38 serving as a gas supply passage. In FIG. 1, the number of valves 34 connected in parallel is three, but the number of valves 34 connected in parallel may be two or four or more.

The valve 31 is arranged between the gas supply source 2 and the filling tank 32. The valve 31 is an on-off valve and can be controlled to enter the open or closed state by the controller 5. The filling tank 32 is configured so that the processing gas can be filled therein. If the valve 31 is controlled to enter the open state by the controller 5, the filling tank 32 is supplied and filled with the processing gas from the gas supply source

The gas supply pipe 36 communicates with a space in the filling tank 32 and causes the processing gas in the filling tank 32 to flow to a plurality of gas supply pipes 37-1 to 37-3. A plurality of gas supply pipes 37-1 to 37-3 are connected in parallel to one another between the gas supply pipe 36 and the gas supply pipe 38.

A plurality of valves 34-1 to 34-3 correspond to a plurality of gas supply pipes 37-1 to 37-3. Each of the valves 34-1 to 34-3 is arranged in a corresponding one of a plurality of gas supply pipes 37-1 to 37-3. The valve 34-1 is disposed in the gas supply pipe 37-1 as, for example, a diaphragm valve and controlled to enter the open or closed state via the air regulator 7-1 under the control of the controller 5. The valve 34-2 is disposed in the gas supply pipe 37-2 as, for example, a diaphragm valve and controlled to enter the open or closed state via the air regulator 7-2 under the control of the controller 5. The valve 34-3 is disposed in the gas supply pipe 37-3 as, for example, a diaphragm valve and controlled to enter the open or closed state via the air regulator 7-3 under the control of the controller 5.

It should be noted that each of the valves 34-1 to 34-3 can be configured as illustrated in FIG. 2. In addition, each of the valves 34-1 to 34-3 can perform an opening/closing operation as illustrated in FIGS. 3A and 3B.

An upstream side of the valve 34-1 in the gas supply pipe 37-1 illustrated in FIG. 1 communicates with the gas supply pipe 36, and a downstream side of the valve 34-1 in the gas supply pipe 37-1 communicates with the gas supply pipe 38. An upstream side of the valve 34-2 in the gas supply pipe 37-2 communicates with the gas supply pipe 36, and a downstream side of the valve 34-2 in the gas supply pipe 37-2 communicates with the gas supply pipe 38. An upstream side of the valve 34-3 in the gas supply pipe 37-3 communicates with the gas supply pipe 36, and a downstream side of the valve 34-3 in the gas supply pipe 37-3 communicates with the gas supply pipe 39. When the corresponding valve 34 is controlled to enter the open state, each of a plurality of gas supply pipes 37-1 to 37-3 supplies the processing gas supplied from the filling tank 32 via the gas supply pipe 36 to the gas supply pipe 38. The gas supply pipe 38 communicates with the processing chamber 4 and supplies the processing gas supplied via the gas supply pipe 36 and a plurality of gas supply pipes 37-1 to 37-3 to the processing chamber 4.

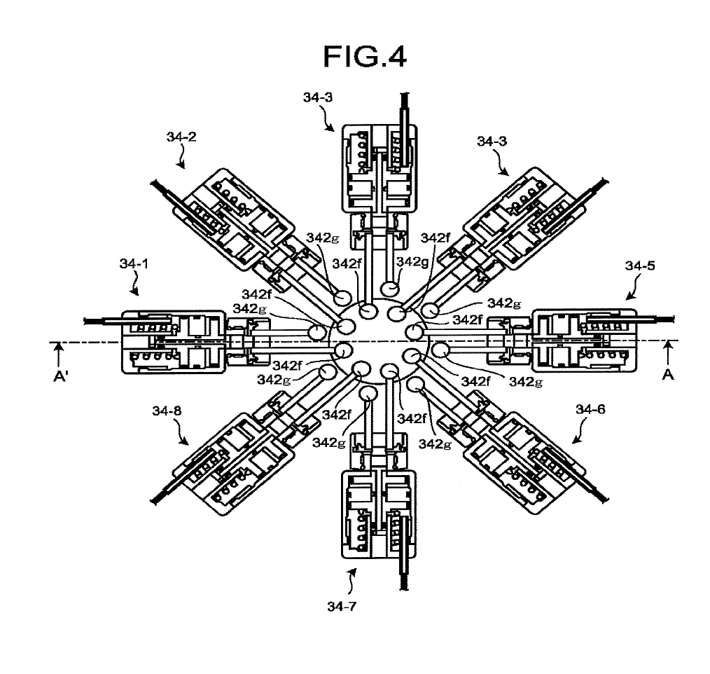

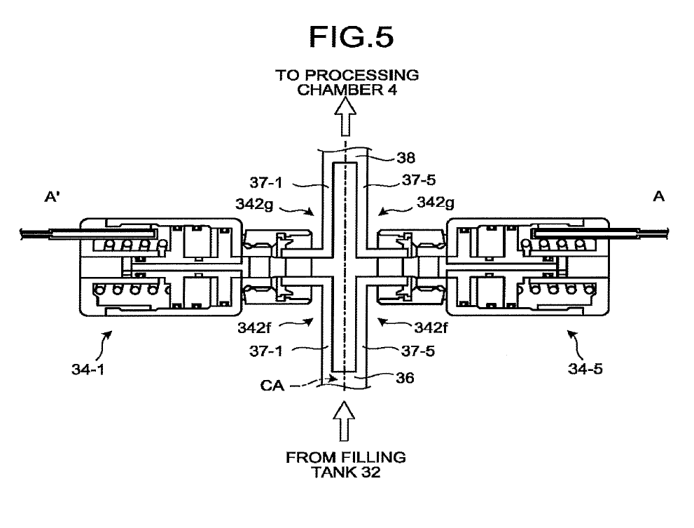

In the parallel configuration of a plurality of valves 34-1 to 34-3 illustrated in FIG. 1, a pipe length from the gas supply pipe 36 to the valves 34-1 and 34-3 is schematically (two-dimensionally) illustrated as being larger than a pipe length from the gas supply pipe 36 to the valve 34-2, but the pipe lengths from the gas supply pipe 36 to the respective valves 34 can be three-dimensionally equalized by implementing with configuration illustrated in FIG. 4 and FIG. 5. FIG. 4 is a plane view illustrating an implementation configuration of a plurality of valves 34-1 to 34-8 corresponding to a portion surrounded by an alternate long and two short dashes line in FIG. 1. FIG. 5 is a sectional view illustrating an implementation configuration of a plurality of valves 34-1 and 34-5, and illustrates a cross section taken along line A′-A in the configuration of FIG. 4. FIG. 4 illustrates an example in which the number of the valves 34 connected in parallel is eight.

For example, as illustrated in FIG. 4, a plurality of valves 34-1 to 34-6 are radially connected to the gas supply passage extending from a gas supply pipe 36 on the upstream side to the gas supply pipe 38 on the downstream side via the gas supply pipes 37-1 to 37-3. In other words, a plurality of valves 34-1 to 34-8 are radially connected to communicate with the gas supply pipe 36 communicated with the filling tank 32, and as illustrated in FIG. 5, the gas supply pipe 38 is arranged on an extension line of a central axis CA of the gas supply pipe 36, and a plurality of valves 34-1 to 34-8 are radially connected to communicate with the gas supply pipe 38 communicated with the processing chamber 4. Further, the processing chamber 4 is also arranged on the extension line of the central axis CA. In other words, as illustrated in FIGS. 4 and 5, a downstream end of the gas supply pipe 36 is connected to communicate with the inlet ports 342f of the valves 34-1 to 34-8 via the gas supply pipes 37-1 to 37-8, and the outlet ports 342g of the valves 34-1 to 34-8 are connected to communicate with an upstream end of the gas supply pipe 38 via the gas supply pipes 37-1-37-8.

With the implementation configuration illustrated in FIGS. 4 and 5, the pipe lengths from the gas supply pipe 36 to the respective valves 34 can he equalized, and the pipe lengths from the respective valves 34 to the gas supply pipe 38 can be equalized, and thus it is possible to equalize the flow rates of the processing gas supplied to the processing chamber 4 via the respective valves 34.

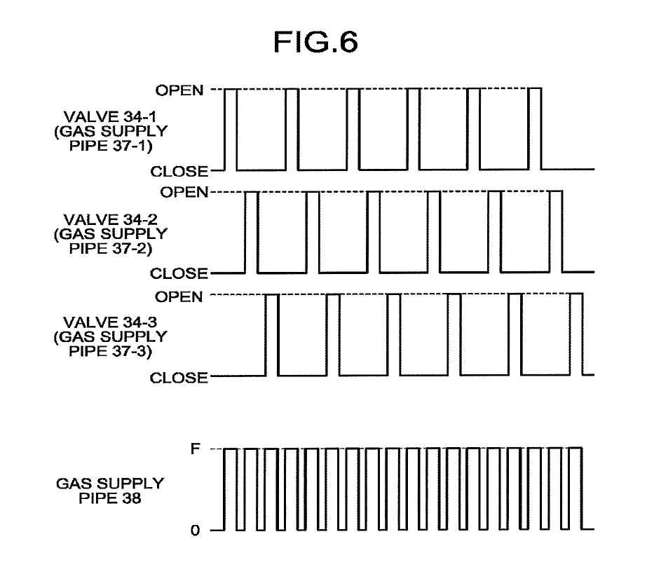

Next, control of a plurality of valves 34-1 to 34-3 by the controller 5 will be described with reference to FIG. 6. FIG. 6 is a timing chart illustrating operations of a plurality of valves 34-1 to 34-3.

As illustrated in FIG. 6, the controller 5 causes a plurality of valves 34-1 to 34-3 to be sequentially opened and closed. In other words, the controller 5 performs control such that a period in which each of a plurality of valves 34-1 to 34-3 enters the open state (an open period) turns sequentially in the order of the valve 34-1→the valve 34-2→the valve 34-3→the valve 34-1 while preventing the open periods of a plurality of valves 34-1 to 34-3 from overlapping. Accordingly, the pulse waveform of the processing gas flow rate in a plurality of gas supply pipes 37-1 to 37-3 corresponds to the open periods of a plurality of valves 34-1 to 34-3. In other words, since a plurality of valves 34-1 to 34-3 are sequentially controlled to enter the open or closed state so that phases of the pulse waveforms of the flow rates of the processing gases in a plurality of gas supply pipes 37-1 to 37-3 are shifted, the frequency of the pulse waveform of the flow rate of the processing gas in the gas supply pipe 38 merged from the gas supply pipes 37-1 to 37-3 is increased to be higher than each of the gas supply pipes 37-1, 37-2, and 37-3 by the parallel number as illustrated in FIG. 6. Accordingly, it is possible to improve the supply efficiency of the processing gas to the processing chamber 4.

As described above, in the first embodiment, in the semiconductor manufacturing apparatus 1, the valves 34 are connected in parallel between the gas supply source 2 and the processing chamber 4. Accordingly, for example, since it is possible to increase the frequency of the pulse waveform of the flow rate of the processing gas by performing control such that a plurality of valves 34-1 to 34-3 enter the open or close state sequentially, it is possible to improve the supply efficiency of the processing gas to the processing chamber 4.

It should be noted that each of the valves 34 is not limited to the normally closed type and may be the normally open type. Alternatively, some valves among a plurality of valves 34-1 to 34-3 may be the normally closed type, and the other valves may be the normally open type.

Alternatively, each of the valves 34 is not limited to the diaphragm valve using a pneumatic actuator but may be, for example, a diaphragm valve using a hydraulic actuator or a diaphragm valve using an electromechanical actuator.

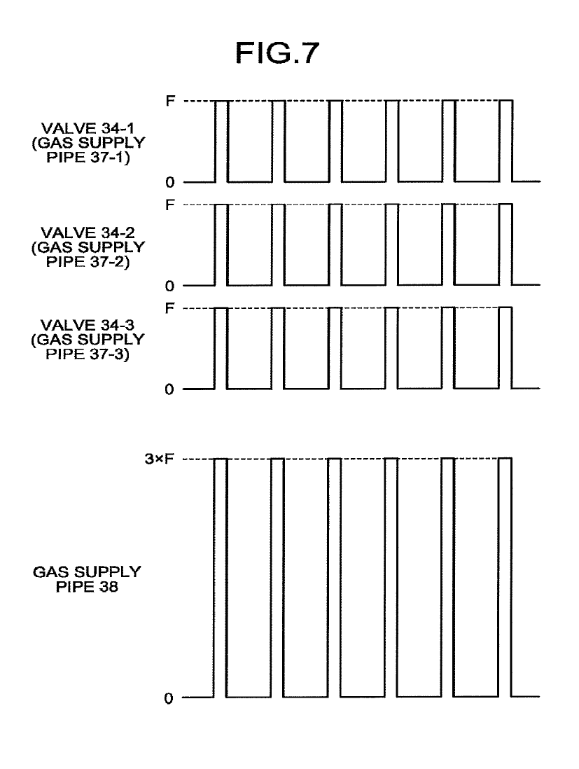

Alternatively, the controller 5 may cause opening/closing timings of a plurality of valves 34-1 to 34-3 to be synchronized with one another. FIG. 7 is a timing chart illustrating a modified example of operations of a plurality of valves 34-1 to 34-3. For example, as illustrated in FIG. 7, it is possible to periodically perform an operation of causing a plurality of valves 34-1 to 34-3 to enter the open state at substantially the same time and causing them to enter the closed state at substantially the same time. Accordingly, the pulse waveforms of the flow rates of the processing gases in a plurality of gas supply pipes 37-1 to 37-3 corresponds to the open periods of a plurality of valves 34-1 to 34-3. In other words, if each of pulse waveform peaks of the flow rates of the processing gases in a plurality of gas supply pipes 37-1 to 37-3 is indicated by a flow rate F, the pulse waveform peak of the processing gas flow rate in the gas supply pipe 38 merged from a plurality of gas supply pipes 37-1 to 37-3 is the parallel number×the flow rate F (3×F in the example of FIG. 7). Therefore, as illustrated in FIG. 7, it is possible to increase the amplitude of the pulse waveform of the processing gas flow rate in the gas supply pipe 38 merged from a plurality of gas supply pipes 37-1 to 37-3 to be higher than the amplitude of each of the gas supply pipes 37-1, 37-2, and 37-3 by the several parallel number. Accordingly, it is possible to improve the supply efficiency of the processing gas to the processing chamber 4.

### Second Embodiment

Next, a semiconductor manufacturing apparatus 201 according to a second embodiment will be described. The following description will proceed focusing on parts different from the first embodiment.

In the first embodiment, the supply efficiency of each processing gas to the processing chamber 4 is improved by connecting the valves 34 between the gas supply source 2 and the processing chamber 4 in parallel, but in the second embodiment, the supply efficiency of each processing gas to the processing chamber 4 is improved by improving the configuration of the valve 34.

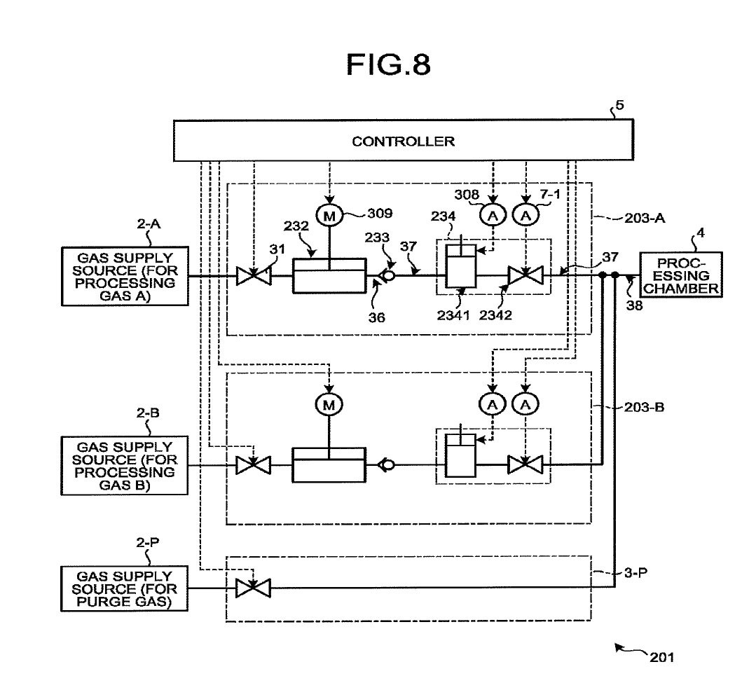

FIG. 8 is a view illustrating a configuration of the semiconductor manufacturing apparatus 201. Specifically, as illustrated in FIG. 8, instead of the gas supply system 3-A and the gas supply system 3-B (see FIG. 1), the semiconductor manufacturing apparatus 201 includes a gas supply system 203-A and a gas supply system 203-B. The gas supply system 203-A is disposed between the gas supply source 2-A and the processing chamber 4 and supplies the processing gas ‘A’ to the processing chamber 4 under the control of the controller 5. The gas supply system 203-B is disposed between the gas supply source 2-B and the processing chamber 4 and supplies the processing gas ‘B’ to the processing chamber 4 under the control of the controller 5.

For example, each gas supply system 203 for the processing gas is configured as illustrated in FIG. 8. The following description will proceed focusing on the configuration for the processing gas ‘A’, hut configurations for other processing gas (the processing gas ‘B’ and the like) are similar to that of the processing gas ‘A’. For the sake of simplification of description, the processing gas ‘A’ is referred to simply as a processing gas, the gas supply source 2-A is referred to simply as a gas supply source 2, and a gas supply system 203-A is referred to simply as a gas supply system 203.

The gas supply system 203 includes a filling tank 232 instead of the filling tank 32 (see FIG. 1), includes a pump valve 234 instead of a plurality of valves 34-1 to 34-3 (see FIG. 1), and further includes a check valve 233.

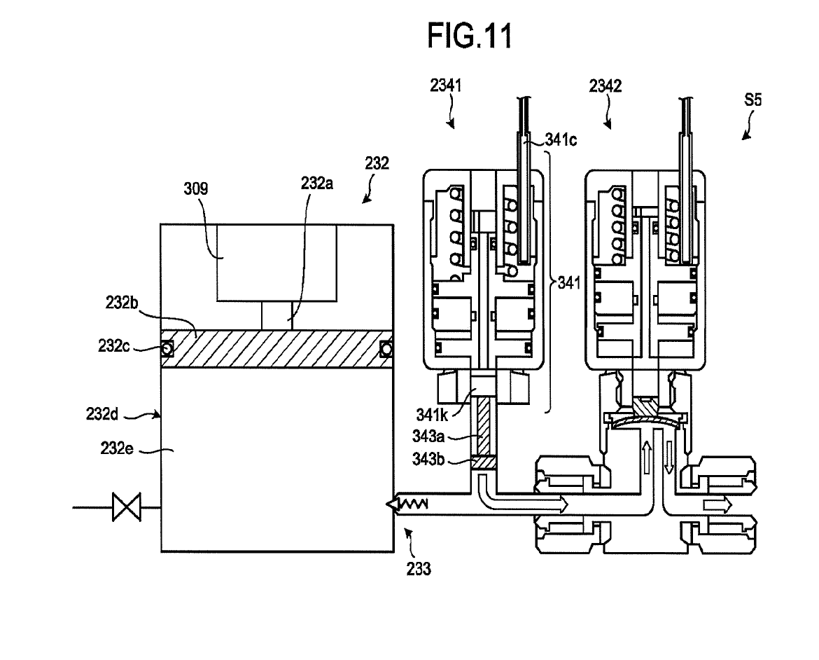

The pump valve 234 is disposed in a gas supply pipe 37 between the gas supply pipe 36 and the gas supply pipe 38 and is configured to be able to pressurize the processing gas in the pipe. The pump valve 234 has a pump mechanism 2341 and an opening/closing mechanism 2342. The pump mechanism 2341 includes a piston rod 343a and a piston 343b (see FIG. 11) in addition to the same configuration as the actuator assembly 341 illustrated in FIG. 2. The opening/closing mechanism 2342 has a similar configuration to the valve (for example, diaphragm valve) 34.

In the pump mechanism 2341, the auxiliary control port 341c (see FIG. 11) is configured to be able to supply, for example, the operating gas (air) adjusted to the high pressure from an air regulator 308 (see FIG. 8) by the controller 5. The air regulator 308 includes a motor, a compressor, an on-off valve, and the like. The controller 5 can control an air compression operation by the compressor by controlling a rotation operation of the motor and can control whether or not the high pressure air is supplied to the auxiliary control port 341c by performing control such that the on-off valve is opened or closed.

The piston rod 343a couples the piston rod 341k in the actuator assembly 341 with the piston 343b and transmits movement of the piston rod 341k to the piston 343b. For example, the controller 5 can synchronize the processing gas pressurizing operation performed by the pump mechanism 2341 with the opening/closing operation performed by the opening/closing mechanism 2342. In other words, the pump mechanism 2341 and the opening/closing mechanism 2342 can operate as the integral pump valve 234 in cooperation with each other. Accordingly, the pump valve 234 can pressurize the processing gas supplied from the upstream side and supply the pressurized gas to the downstream side, and can increase the gas flow rate which can be supplied to the processing chamber 4 side per unit time as compared with the valve 34 that is unable to pressurize the processing gas.

The check valve 233 is mechanically inserted into the gas supply pipe 36 as the valve (for example, the diaphragm valve) 34 is replaced with the pump valve 234. The check valve 233 allows the flow of the processing gas from the filling tank 232 to the pump valve 234 and can prevent the backward flow of the processing gas from the pump valve 234 to the filling tank 232. Accordingly, the check valve 233 can prevent the backward flow of the processing gas from the pump valve 234 toward the filling tank 232 when the processing gas in the pipe is pressurized by the pump valve 234.

The filling tank 232 is disposed between the gas supply source 2 and the pump valve 234. The filling tank 232 is configured so that the capacity for filling the processing gas is variable. As illustrated in FIG. 11, the filling tank 232 includes a piston rod 232a, a piston 232b, an O ring 232c, a wall portion 232d, and a filling chamber 232e.

In the filling tank 232, the piston rod 232a can be driven in a vertical direction by a motor 309 under the control of the controller 5. The piston rod 232a transmits the movement driven by the motor 309 to the piston 232b. The O ring 232c seals the filling chamber 232e from the space above the piston 232b. Accordingly, the volume of the filling chamber 232e surrounded by the piston 232b and the wall portion 232d can be changed by the controller 5. For example, the filling tank 232 can adjust an amount (pressure) of processing gas to be filled in the filling tank 232 depending on a processing condition of the substrate in the processing chamber 4.

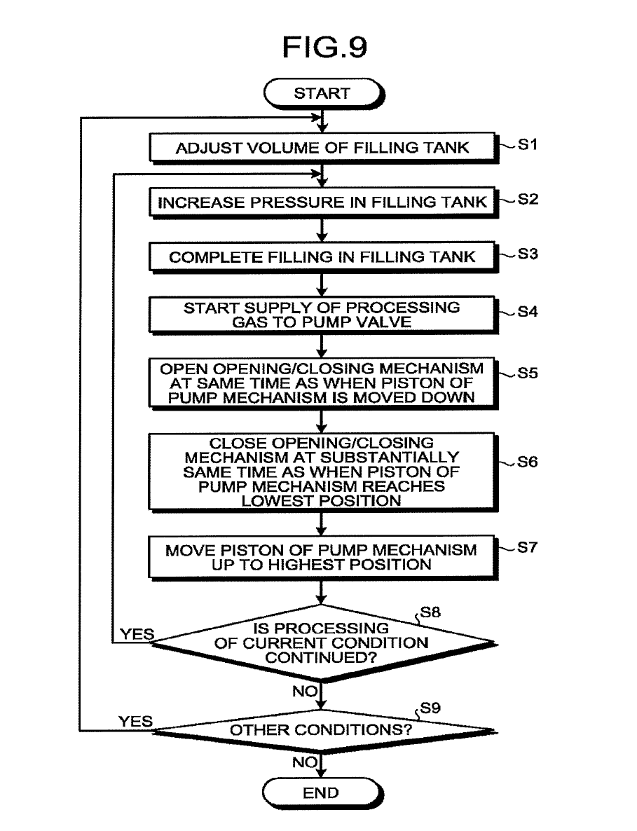

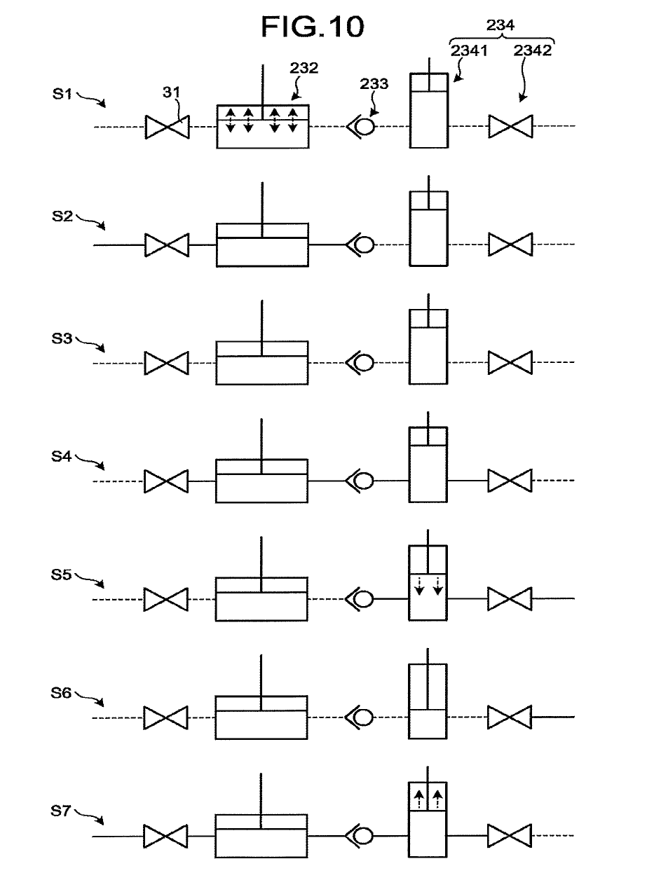

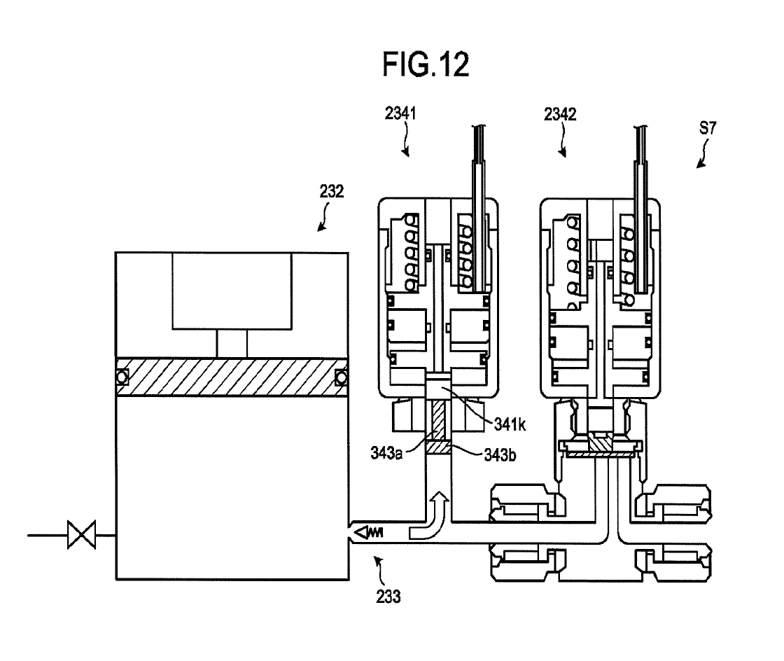

Next, an operation of the semiconductor manufacturing apparatus 201 will be described with reference to FIGS. 9 to 12. FIG. 9 is a flowchart illustrating the operation of the semiconductor manufacturing apparatus 201. FIGS. 10 to 12 are diagrams illustrating the operation of the semiconductor manufacturing apparatus 201. An operation of the gas supply system 203 (for example, the gas supply system 203-A) for one processing gas (for example, the processing gas A) in the semiconductor manufacturing apparatus 201 is exemplarily described with reference to FIGS. 9 and 12, but the same can apply to the other gas supply systems 203 (for example, the gas supply system 203-3).

In the semiconductor manufacturing apparatus 201, as an initial setting prior to a substrate processing cycle such as an ALD cycle, the volume of the filling tank 232 in the gas supply system 203 is adjusted according to the processing condition of the substrate to be started (S1). For example, the volume of the filling chamber 232e can be changed by operating the piston 232b as indicated by a dashed arrow in FIG. 10. At this time, all of the valve 31, the check valve 233, and the opening/closing mechanism 2342 are in the closed state, and the piston 343b of the pump mechanism 2341 is fixed to the highest position. Further, each pipe is in the inactive state as indicated by a broken line in FIG. 10.

The gas supply system 203 performs a process of S2 to S7 as the substrate processing cycle such as an ALD cycle.

Specifically, the gas supply system 203 opens the valve 31 and transmits the processing gas from the gas supply source 2 to the filling tank 232 to increase the pressure in the filling tank 232 (S2). At this time, the check valve 233 and the opening/closing mechanism 2342 are both in the closed state, and the piston 343b of the pump mechanism 2341 is fixed to the highest position. Further, the pipe from the gas supply source 2 to the check valve 233 is in the active state as indicated by a solid line in FIG. 10, but each pipe on the downstream side from the check valve 233 is in the inactive state as indicated by a broken line.

The gas supply system 203 closes the valve 31 when the filling of the processing gas into the filling tank 232 is completed. At this time, all of the valve 31, the check valve 233, and the opening/closing mechanism 2342 are in the closed state, and the piston 343b of the pump mechanism 2341 is fixed to the highest position. Further, each pipe is in the inactive state as indicated by a broken line in FIG. 10.

In the gas supply system 203, as the pressure of the processing gas in the filling tank 232 is higher than the pressure in the pipe between the check valve 233 and the opening/closing mechanism 2342, the check valve 233 starts to operate and enters the open state, and the supply of the processing gas from the filling tank 232 to the pump valve 234 side is started (34). At this time, both the valve 31 and the opening/closing mechanism 2342 are in the closed state, and the piston 343b of the pump mechanism 2341 is fixed to the highest position. As indicated by a solid line in FIG. 10, the pipe from the valve 31 to the opening/closing mechanism 2342 is in the active state, but as indicated by a broken line, the pipe on the upstream side from the valve 31 and the pipe on the downstream side from the opening/closing mechanism 2342 are in the inactive state.

The gas supply system 203 moves the piston 343b of the pump mechanism 2341 in the pump valve 234 down while opening the opening/closing mechanism 2342 (S5). At this time, both the valve 31 and the check valve 233 are in the closed state. Further, the pipe from the gas supply source to the check valve 233 is in the inactive state as indicated by a broken line in FIG. 10, but each pipe on the downstream side from the check valve 233 is in the active state as indicated by a solid line. Accordingly, as illustrated in FIG. 11, the processing gas in the pipe from the check valve 233 to the opening/closing mechanism 2342 is pressurized by the pump mechanism 2341 and fed to the opening/closing mechanism 2342 side, and the pressurized processing gas flows from the inlet opening 342d to the outlet opening 342e of the opening/closing mechanism 2342 and is supplied to the processing chamber 4 side. A speed at which the piston 343b of the pump mechanism 2341 is moved down can be adjusted depending on the supply time of the processing gas (the pulse width of the pulse waveform of the flow rate).

The gas supply system 203 closes the opening/closing mechanism 2342 at substantially the same time as when the piston 343b of the pump mechanism 2341 in the pump valve 234 reaches the lowest position (S6). At this time, both the check valve 233 and the opening/closing mechanism 2342 are in the closed state. The pipe from the gas supply source 2 to the opening/closing mechanism 2342 is in the inactive state as indicated by a broken line in FIG. 10, but the pipe on the downstream side from the opening/closing mechanism 2342 is in the active state as indicated by a solid line.

The gas supply system 203 moves the piston 343b of the pump mechanism 2341 in the pump valve 234 up to the highest position (S7). At this time, the opening/closing mechanism 2342 is in the closed state, and both the valve 31 and the check valve 233 are in the open state. The pipe on the downstream side from the opening/closing mechanism 2342 is in the inactive state as indicated by a broken line in FIG. 10, and each pipe from the gas supply source 2 to the opening/closing mechanism 2342 is in the active state as indicated by a solid line. Accordingly, as illustrated in FIG. 12, the processing gas is supplied into the pipe from the gas supply source 2 to the opening/closing mechanism 2342. The speed at which the piston 343b of the pump mechanism 2341 is moved up can be set to the highest speed.

When the substrate processing cycle according to the current processing condition is continued (Yes in S6), the semiconductor manufacturing apparatus 201 causes the process to return to S2, and when the substrate processing cycle according to the current processing condition ends (No in S8), the process proceeds to S9. When the semiconductor manufacturing apparatus 201 desires to perform a substrate processing cycle according to other processing conditions (Yes in S9), the process returns to S1, and if there is no plan to perform a substrate processing cycle according to another processing condition (No in S9), the process ends.

It should be noted that steps (S2 to S7) in the substrate processing cycle can be performed, for example, at a high speed of less than 1 second. In the substrate processing cycle (S2 to S7), the purging operation of the processing chamber 4 can be performed in S6 to S7.

As described above, in the second embodiment, in each of the gas supply systems 203 of the semiconductor manufacturing apparatus 201, the pump valve 234 can pressurize the processing gas supplied from the upstream side and supply the processing gas to the downstream side, and the gas flow rate which can be supplied to the processing chamber 4 side per unit time can be increased as compared with the valve 34 that is unable to pressurize the processing gas. Accordingly, it is possible to improve the supply efficiency of the processing gas to the processing chamber 4.

In the second embodiment, in each of the gas supply systems 203 of the semiconductor manufacturing apparatus 201, the filling tank 232 is configured such that the capacity for filling the processing gas is variable. Accordingly, since the amount (pressure) of the processing gas filled in the filling tank 232 can be adjusted to an appropriate amount according to the processing condition of the substrate in the processing chamber 4, the supply efficiency of the processing gas to the processing chamber 4 can be improved.

It should be noted that the check valve 233 in each of the gas supply systems 203 may be replaced by an on-off valve which is controlled to enter the open or closed state by the controller 5 as long as the timing operation illustrated in FIGS. 9 and 10 can be implemented.

Alternatively, the semiconductor manufacturing apparatus 201 is, for example, an ALD apparatus, but the concept of the present embodiment is also applicable to other semiconductor manufacturing apparatuses as long as it is an apparatus that supplies the processing gas to the processing chamber 4 and processes the substrate. For example, the semiconductor manufacturing apparatus 201 may be a film forming apparatus such as a chemical vapor deposition (CVD) apparatus or a physical vapor deposition (PVD) apparatus or may be an etching apparatus such as a reactive ion etching (RIE) apparatus.

### Third Embodiment

Next, a semiconductor manufacturing apparatus 0 according to a third embodiment will be described. The following description will proceed focusing on parts different from the first embodiment.

In the first embodiment, the equalization of the flow rates of the respective valves 34 in the parallel configuration of a plurality of valves 34 is realized by employing the three-dimensional implementation configuration, but the third embodiment, the equalization of the flow rates in the parallel configuration is implemented using the valve 34 and the pump valve 234 in combination.

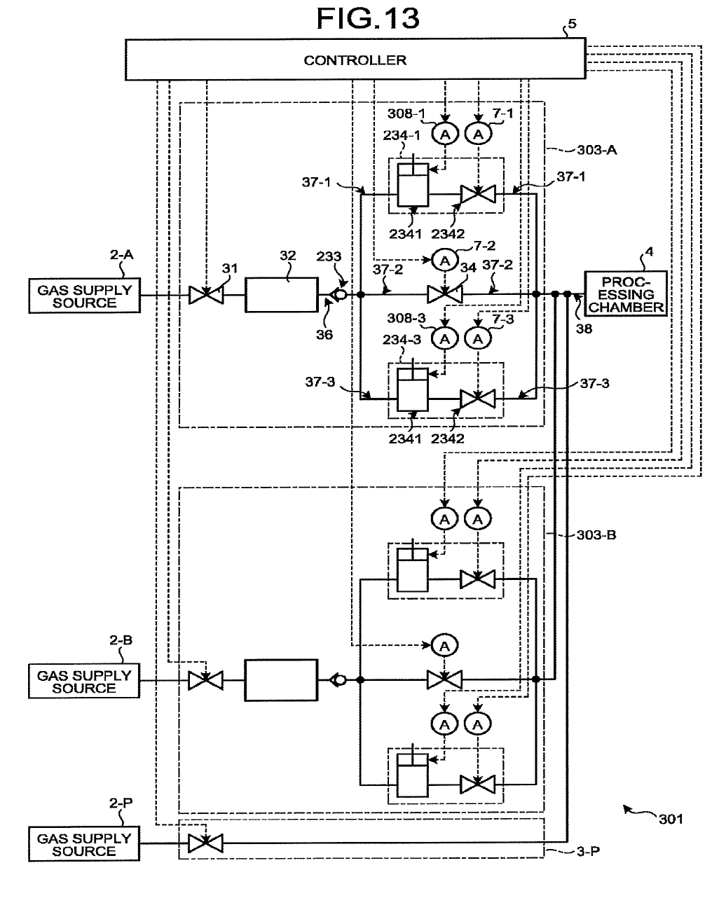

FIG. 13 is a view illustrating a configuration of a semiconductor manufacturing apparatus 301. Specifically, the semiconductor manufacturing apparatus 301 includes a gas supply system 303-A and a gas supply system 303-B instead of the gas supply system 3-A and the gas supply system 3-B (see FIG. 1) as illustrated in FIG. 13. The gas supply system 303-A is disposed between the gas supply source 2-A and the processing chamber 4 and supplies the processing gas A to the processing chamber 4 under the control of the controller 5. The gas supply system 303-B is disposed between the gas supply source 2-B and the processing chamber 4 and supplies the processing gas B to the processing chamber 4 under the control of the controller 5.

For example, each gas supply system 303 for the processing gas is configured as illustrated in FIG. 13. The following description will proceed focusing on the configuration for the processing gas ‘A’, but configurations for other processing gas (the processing gas ‘B’ and the like) are similar to that of the processing gas ‘A’. For the sake of simplification of description, the processing gas ‘A’ is referred to simply as a processing gas, and a gas supply system 303-A is referred to simply as a gas supply system 303.

The gas supply system 303 includes a plurality of pump valves 234-1 and 234-3 instead of a plurality of valves 34-1 and 34-3 (see FIG. 1) and further includes a check valve 233. Each of the pump valves 234-1 and 234-3 is similar to the pump valve 234 in the second embodiment. Similarly to the second embodiment, the check valve 233 is mechanically inserted into the gas supply pipe 36 as the valve 34 is replaced with the pump valve 234.

For example, when a plurality of gas supply pipes 37-1 to 37-3 in a parallel configuration of a plurality of valves 34-1 to 34-3 are two-dimensionally mounted as illustrated in FIG. 1, the pipe length from the gas supply pipe 36 to the valves 34-1 and 34-3 is larger than the pipe length from the gas supply pipe 36 to the valve 34-2. To this end, the valves 34-1 and 34-3 corresponding to the pipes having a long pipe length in the configuration of FIG. 1 are replaced with the pump valve 234-1 and the pump valve 234-3 having a higher gas supply capability than the valve 34-2 to thereby implement the parallel connection of the pump valve 234-1, the valve 34-2, and the pump valve 234-3 illustrated in FIG. 13. Accordingly, it is possible to absorb the pressure difference of the processing gas in the pipe which can be caused by the pipe length difference in the gas supply pipes 37-1 to 37-3 through the difference in the gas supply capability between the pump valves 234-1 and 234-3 and the valve 34-2, and it is possible to equalize the flow rates in the parallel configuration.

As described above, in the third embodiment, in the semiconductor manufacturing apparatus 301, the valves 34-1 and 34-3 corresponding to the pipes having a long pipe length in the configuration of FIG. 1 are replaced with the pump valve 234-1 and the pump valve 234-3 having a higher gas supply capability than the valve 34-2 to thereby implement the parallel connection of the pump valve 234-1, the valve 34-2, and the pump valve 234-3 illustrated in FIG. 13. Accordingly, it is possible to equalize the flow rates in the parallel configuration.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus, comprising:
a processing chamber in which a substrate is processed;
a first gas supply pipe disposed between a gas supply source and the processing chamber;
a first valve disposed in the first gas supply pipe, the first valve including a first valve seat forming a first opening, a first diaphragm, and a first pressing member capable of pressing the first diaphragm against the first valve seat;
a second gas supply pipe disposed between the gas supply source and the processing chamber, the second gas supply pipe being connected to the first gas supply pipe in parallel; and
a second valve disposed in the second gas supply pipe, the second valve including a second valve seat forming a second opening, a second diaphragm, and a second pressing member capable of pressing the second diaphragm against the second valve seat.

2. The semiconductor manufacturing apparatus according to claim 1, wherein
the first valve and the second valve are radially connected to a gas supply passage from an upstream side to a downstream side of the first gas supply pipe and the second gas supply pipe.

3. The semiconductor manufacturing apparatus according claim 2, wherein
a length of the first gas supply pipe and a length of the second gas supply pipe are substantially equal.

4. The semiconductor manufacturing apparatus according claim 1, wherein
the first gas supply pipe is longer than the second gas supply pipe,
the first valve a pump valve capable of pressurizing a processing gas, and
the second valve is a valve that is not capable of pressurizing the processing gas.

5. The semiconductor manufacturing apparatus according to claim 4, wherein
the first valve includes an opening/closing mechanism having the first valve seat, the first diaphragm, and the first pressing member and a pressurization mechanism disposed on an upstream side of the first opening, and
the second valve includes an opening/closing mechanism including the second valve seat, the second diaphragm, and the second pressing member, the second valve not including a pressurization mechanism on an upstream side of the second opening.

6. The semiconductor manufacturing apparatus according to claim 5, wherein
the pressurization mechanism in the first valve includes a piston that pressurizes an inside of a pipe on the upstream side of the first opening.

7. The semiconductor manufacturing apparatus according to claim 1, further comprising,
a controller that synchronizes an opening/closing timing of the first valve with an opening/closing timing of the second valve.

8. The semiconductor manufacturing apparatus according claim 1, further comprising,
a controller that causes the first valve and the second valve to be sequentially opened or closed.

9. The semiconductor manufacturing apparatus according to claim 1, further comprising,
a third gas supply pipe disposed between the gas supply source and the processing chamber, the third gas supply pipe being connected to the first gas supply pipe and the second gas supply pipe in parallel; and
a third valve disposed in the third gas supply pipe, the third valve including a third valve seat forming a third opening, a third diaphragm, and a third pressing member capable of pressing the third diaphragm against the third valve seat.

10. The semiconductor manufacturing apparatus according to claim 9, further comprising,
a controller that synchronizes an opening/closing timing of the first valve, an opening/closing timing of the second valve, arid opening/closing timing of the third valve with one another.

11. The semiconductor manufacturing apparatus according to claim 9, further comprising,
a controller that causes the first valve, the second valve, and the third valve to be sequentially opened or closed.

12. The semiconductor manufacturing apparatus according claim 1, wherein
the semiconductor manufacturing apparatus is an ALD apparatus.

13. A semiconductor manufacturing apparatus, comprising:
a processing chamber in which a substrate is processed;
a gas supply pipe that connects a gas supply source with the processing chamber; and
a pump valve disposed in the gas supply pipe and capable of pressurizing a processing gas.

14. The semiconductor manufacturing apparatus according to claim 13, wherein
the pump valve includes an opening/closing mechanism and a pressurization mechanism disposed on an upstream side of the opening/closing mechanism, and
the semiconductor manufacturing apparatus further comprises a controller that synchronizes a timing to cause the opening/closing mechanism to enter an open state with a timing for pressurizing the processing gas through the pressurization mechanism.

15. The semiconductor manufacturing apparatus according claim 14, wherein
the opening/closing mechanism includes a valve seat forming an opening, a diaphragm, and a pressing member capable of pressing the diaphragm against the valve seat.

16. The semiconductor manufacturing apparatus according to claim 14, wherein
the pressurization mechanism includes a piston, and as the piston is moved down, an inside of a pipe on the upstream side of the opening/closing mechanism is pressurized.

17. The semiconductor manufacturing apparatus according to claim 16, wherein
the controller causes the opening/closing mechanism to be closed at a timing to cause the piston to move to a lowest position.

18. The semiconductor manufacturing apparatus according to claim 13, further comprising,
a filling tank disposed in a gas supply passage between the gas supply source and the pump valve and having a variable capacity for filling the processing gas.

19. The semiconductor manufacturing apparatus according claim 18, further comprising,
a check valve or an on-off valve disposed between the pump valve and the filling tank.

20. The semiconductor manufacturing apparatus according to claim 13, wherein
the semiconductor manufacturing apparatus is an ALD apparatus.
